(19) United States
(12) Patent Application Publication
(10) Pub. No.: US 2009/0151636 A1
(43) Pub. Date: Jun. 18, 2009

(54) RPSC AND RF FEEDTHROUGH

(75) Inventors: John M. White, Hayward, CA (US); Bradley O. Stimson, Monte Sereno, CA (US); Jozef Kudela, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/271,613

(22) Filed: Nov. 14, 2008

Related U.S. Application Data
(60) Provisional application No. 60/988,694, filed on Nov. 16, 2007.

(51) Int. Cl. C23C 16/513; C23C 16/511

(52) U.S. Cl. 118/723 ME; 118/723 R

(57) ABSTRACT

The present invention generally comprises an apparatus having an RF choke and a remote plasma source combined into a single unit. Process gases may be introduced to the chamber via the showerhead assembly which may be driven as an RF electrode. The gas feed tube may provide process gases and the cleaning gases to the process chamber. The inside of the gas feed tube may remain at a zero RF field to avoid premature gas breakdown within the gas feed tube that may lead to parasitic plasma formation between the gas source and the showerhead during processing. Igniting the cleaning gas plasma within the gas feed tube permits the plasma to be ignited closer to the processing chamber. Thus, RF current travels along the outside of the apparatus during deposition and microwave current ignites a plasma within the apparatus before feeding the plasma to the processing chamber.

### CROSS-REFERENCE TO RELATED APPLICATIONS

This application claims benefit of United States provisional patent application Ser. No. 60/988,694 (APPM/12277L), filed Nov. 16, 2007, which is herein incorporated by reference.

### BACKGROUND OF THE INVENTION

1. Field of the Invention

Embodiments of the present invention generally relate to an apparatus having both an RF choke and a remote plasma source combined into a single unit.

2. Description of the Related Art

As demand for larger flat panel displays and solar panels continues to increase, so must the size of the substrate and hence, the processing chamber. To deposit films on larger substrates, higher RF current is sometimes necessary. One method for depositing material onto a substrate for flat panel displays or solar panels is plasma enhanced chemical vapor deposition (PECVD). In PECVD, process gases may be introduced into the process chamber through a showerhead and ignited into a plasma by an RF current applied to the showerhead. As substrate sizes increase, the RF current applied to the showerhead may also correspondingly increase. With the increase in RF current, the possibility of premature gas breakdown prior to the gas passing through the showerhead increases as does the possibility of parasitic plasma formation above the showerhead. During PECVD processing, material sometimes will deposit on areas of the chamber in addition to the substrate. The chamber may then need to be cleaned.

Therefore, there is a need in the art for an RF choke to reduce premature gas breakdown and parasitic plasma formation as well as a remote plasma source for cleaning the processing chamber.

### SUMMARY OF THE INVENTION

The present invention generally comprises an apparatus having both an RF choke as well as a remote plasma source combined into a single unit. In one embodiment, a remote plasma source comprises a metal containing source body having a first end, a second end, and a center portion coupled between the first end and the second end, the source body having an inner surface extending between the first end and the second end through the central portion, one or more dielectric antennas disposed within the center portion, and one or more ferrite elements coupled to and at least partially surrounding an outer surface of the center portion.

In another embodiment, a remote plasma source comprises a metal containing source body having a first end, a second end, and a center portion coupled between the first end and the second end, the source body having an inner surface extending between the first end and the second end through the central portion, a conductive coaxial element extending within the source body and spaced from the inner surface, and a dielectric spacer coupled between the first end and the conductive coaxial element.

In another embodiment, an apparatus comprises a processing chamber, a remote plasma source, the remote plasma source having a metal containing source body comprising a first end, a second end, and a central portion coupled therebetween, the source body having an inner surface, the second end coupled to ground, and the first end coupled with the processing chamber, an RF power source coupled to the first end of the remote plasma source, a microwave power source coupled with the remote plasma source, and a gas source coupled with the remote plasma source.

In another embodiment, a method of coupling RF current and remote plasma to a processing chamber comprises flowing an RF current along an outside surface of a remote plasma source body from a first end of the remote plasma source body to a second end of the remote plasma source body, flowing a microwave current into a center passage of the remote plasma source body, flowing a processing gas within the center passage of the remote plasma source body, and igniting a plasma within the remote plasma source body.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PECVD apparatus according to one embodiment of the invention.

FIG. 2 is a schematic cross sectional view of a remote plasma source/RF choke unit according to one embodiment of the invention.

FIG. 3 is a schematic cross sectional view of a remote plasma source/RF choke unit according to another embodiment of the invention.

FIG. 4 is a schematic cross sectional view of a remote plasma source/RF choke unit according to another embodiment of the invention.

FIG. 5 is a schematic cross sectional view of a remote plasma source/RF choke unit according to another embodiment of the invention.

FIG. 6 is a schematic cross sectional view of a remote plasma source/RF choke unit according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises an apparatus having an RF choke and a remote plasma source combined into a single unit. Process gases may be introduced to the chamber via the showerhead assembly which may be driven as an RF electrode. The gas feed tube may provide process gases and the cleaning gases to the process chamber. The inside of the gas feed tube may remain at a zero RF field to avoid premature gas breakdown within the gas feed tube that may lead to parasitic plasma formation between the gas source and the showerhead during processing. Igniting the cleaning gas plasma within the gas feed tube permits the plasma to be ignited closer to the processing chamber. Thus, RF current travels along the outside of the apparatus during deposition and microwave current ignites a plasma within the apparatus before feeding the plasma to the processing chamber.

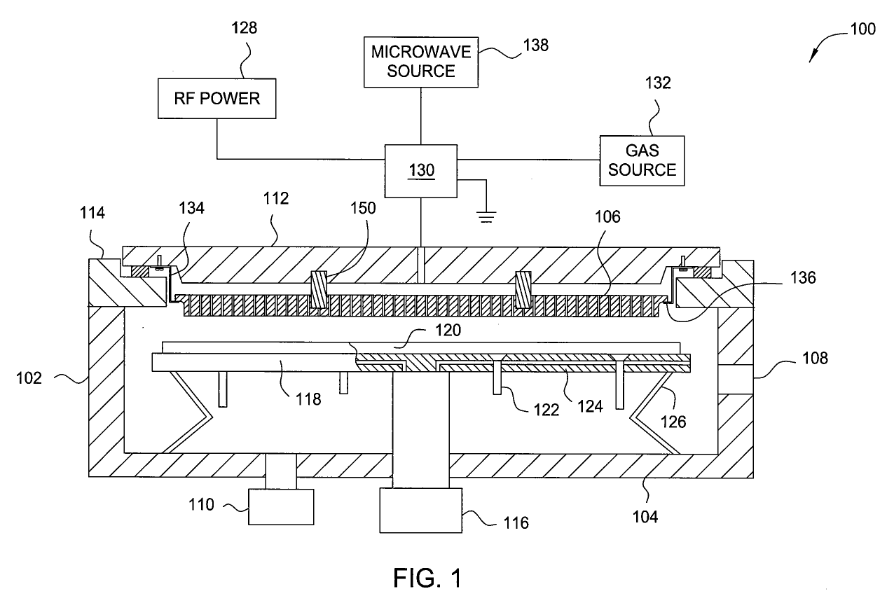

FIG. 1 is a cross sectional view of a PECVD apparatus according to one embodiment of the invention. The apparatus includes a chamber 100 in which one or more films may be deposited onto a substrate 120. One suitable PECVD apparatus which may be used is available from AKT America, Inc., a subsidiary of Applied Materials, Inc., located in Santa Clara, Calif.. While the description below will be made in reference to a PECVD apparatus, it is to be understood that the invention is equally applicable to other processing chambers as well, including those made by other manufacturers.

The chamber 100 generally includes walls 102, a bottom 104, a showerhead 106, and susceptor 118 which define a process volume. The process volume is accessed through a slit valve opening 108 such that the substrate 120 may be transferred in and out of the chamber 100. The susceptor 118 may be coupled to an actuator 116 to raise and lower the susceptor 118. Lift pins 122 are moveably disposed through the susceptor 118 to support a substrate 120 prior to placement onto the susceptor 118 and after removal from the susceptor 118. The susceptor 118 may also include heating and/or cooling elements 124 to maintain the susceptor 118 at a desired temperature. The susceptor 118 may also include grounding straps 126 to provide RF grounding at the periphery of the susceptor 118.

The showerhead 106 is coupled to a backing plate 112 by a fastening mechanism 150. The showerhead 106 may be coupled to the backing plate 112 by one or more coupling supports 150 to help prevent sag and/or control the straightness/curvature of the showerhead 106. In one embodiment, twelve coupling supports 150 may be used to couple the showerhead 106 to the backing plate 112. The coupling supports 150 may include a fastening mechanism such as a nut and bolt assembly. In one embodiment, the nut and bolt assembly may be made with an electrically insulating material. In another embodiment, the bolt may be made of a metal and surrounded by an electrically insulating material. In still another embodiment, the showerhead 106 may be threaded to receive the bolt. In yet another embodiment, the nut may be formed of an electrically insulating material. The electrically insulating material helps to prevent the coupling supports 150 from becoming electrically coupled to any plasma that may be present in the chamber 100. Additionally and/or alternatively, a center coupling mechanism may be present to couple the backing plate 112 to the showerhead 106. The center coupling mechanism may surround a backing plate support ring (not shown) and be suspended from a bridge assembly (not shown). The showerhead 106 may additionally be coupled to the backing plate 112 by a bracket 134. The bracket 134 may have a ledge 136 upon which the showerhead 106 may rest. The backing plate 112 may rest on a ledge 114 coupled with the chamber walls 102 to seal the chamber 100.

A gas source 132 is coupled to the backing plate 112 to provide both processing gas and cleaning gas through gas passages in the showerhead 106 to the substrate 120. The processing gases travel through a remote plasma source/RF choke unit 130. A vacuum pump 110 is coupled to the chamber 100 at a location below the susceptor 118 to maintain the process volume 106 at a predetermined pressure. A RF power source 128 is coupled to the backing plate 112 and/or to the showerhead 106 to provide a RF current to the showerhead 106. The RF current creates an electric field between the showerhead 106 and the susceptor 118 so that a plasma may be generated from the gases between the showerhead 106 and the susceptor 118. Various frequencies may be used, such as a frequency between about 0.3 MHz and about 200 MHz. In one embodiment, the RF current is provided at a frequency of 13.56 MHz.

Between processing substrates, a cleaning gas may be provided to the remote plasma source/RF choke unit 130 so that a remote plasma is generated and provided to clean the chamber 100 components. The cleaning gas may be further excited by the RF power source 128 provided to the showerhead 106. Suitable cleaning gases include but are not limited to NF₃, F₂, and SF₆. The spacing between the top surface of the substrate 120 and the showerhead 106 may be between about 400 mil and about 1,200 mil. In one embodiment, the spacing may be between about 400 mil and about 800 mil.

The RF current from the RF power source 128 and the processing gas from the gas source 132 flow through the common remote plasma source/RF choke unit 130 to the processing chamber 100. The remote plasma source/RF choke unit 130 is shown as grounded in FIG. 1, but it is to be understood that by grounded the plasma source/RF choke unit 130 completes the RF return path by returning to the source driving the current. Coupling the gas and the RF power through a common location may, on its face, appear to be a recipe for disaster. However, RF current has a “skin effect” in traveling on conductive surfaces. RF current travels as close as possible to the source driving it. Thus, RF current travels on the surface of a conductive element and penetrates only to a certain, predeterminable depth (i.e., the skin) of the conductive element. The predeterminable depth may be calculated as a function of the maximum RF current to be applied. Thus, when a conductive element is thinner than the predetermined depth of the RF current penetration, the RF current may directly interact with the gas flowing therein.

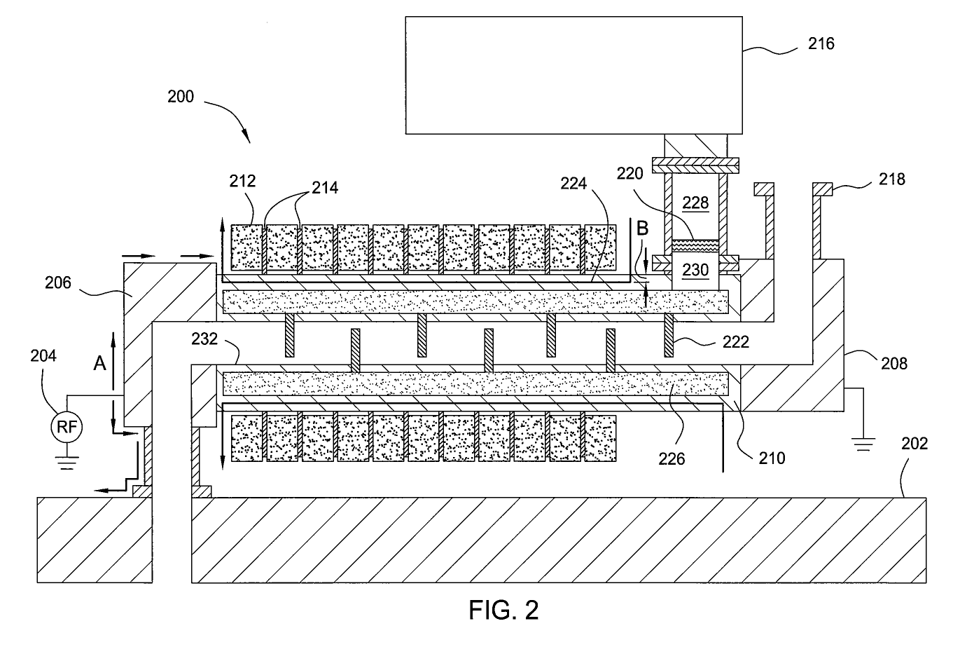

FIG. 2 is a schematic cross sectional view of a remote plasma source/RF choke unit 200 according to one embodiment of the invention. One end block 206 of the unit 200 is coupled to a backing plate 202 of a processing chamber. An RF source 204 is shown coupled with the end block 206. Another end block 208 is shown coupled to ground. It is to be understood that by grounded the end block 208 completes the RF return path by returning to the source driving the current. In between the end blocks 206, 208, a middle section 210 is present. The end blocks 206, 208 and the middle section 210 may comprise a conductive material. In one embodiment, the conductive material comprises copper. In another embodiment, the conductive material comprises aluminum. The RF current may travel on the outside surface of the end blocks 206, 208 as well as the middle section 210 as shown by arrows “A”. Due to the “skin effect” mentioned above, the inside of the end blocks 206, 208 and the middle section 210 have no RF current therein.

To dissipate the RF current along the unit 200, the middle section 210 may have one or more ferrite disks 212 coupled therearound. The ferrite material helps to dissipate the RF current as it travels along the middle section 210 on the way to ground. As the RF current flows along the ferrite material, the RF current dissipates such that at the location where the middle section 210 couples to the end block 208, the RF current is substantially reduced from the RF current applied at the end block 206. In between the ferrite disks 212, one or more fins 214 may extend from the middle section 210. The fins 214 may comprise a conductive material and be coupled with an outer surface of the middle section 210. The fins 214 extend from the middle section 210 and are coupled between adjacent ferrite disks 212. The RF current will travel along the middle section 210, encounter a fin 214, travel along the fin 214, and return to the middle section 210. Thus, the fins 214 increase the surface area of the ferrite disks 212 to which the RF current is exposed. In so doing, the path that the RF current must travel to reach ground is also increased. By increasing the RF path to ground and increasing the exposure to the ferrite disks 212, the RF current may be dissipated.

Because an RF current is traveling along the outside surface of the middle section 210, the middle section 210 may increase in temperature. To control the temperature of the middle section 210, one or more cooling channels 224 may be bored into the middle section 210. The cooling channels 224 may be disposed a distance represented by arrows “B” from the outside surface of the middle section 210 to ensure the cooling fluid flowing therein is not exposed to an RF current. In one embodiment, the cooling channels 224 may comprise a dielectric material. At the location where the cooling fluid exits and enters the cooling channels 224, the material may comprise a dielectric material to prevent exposure to RF current. The cooling fluid may flow from one end block 208 to another end block 206. In one embodiment, the cooling fluid may counterflow from one end block 206 to another end block 208.

The processing gas may flow from the processing gas source (not shown) and enter the unit 200 through a gas feed 218. When the processing chamber is operating in deposition or processing mode, the processing gas may simply pass through the unit 200. However, when the chamber is ready for cleaning, the processing gas may be ignited within the unit 200 to form a plasma. The plasma is ignited in the unit 200 remote from the processing chamber and then fed through the end block 206 and through the backing plate 202 to the processing chamber. Within the unit 200, the cleaning gas may be exposed to a microwave current from a microwave source 216 that is coupled to the unit 200. While the embodiments discussed herein will exemplify a microwave source, it is to be understood that other sources may be used.

The microwave current travels from the microwave source 216 through a dielectric window 220 to the unit 200. The dielectric window 220 separates the microwave source 216 from the unit 200. The area 228 on the side of the dielectric window 220 closest to the microwave source 216 is at atmospheric pressure while the area 228 on the other side of the dielectric window 220 is at the pressure of the gas flowing through the unit 200. A dielectric filler 226 may be disposed within the middle section 210 and coupled with the area 230 such that the microwave current will travel along the dielectric filler 226 for a substantial length of the middle section 210. The dielectric filler 226 may aid in transferring the microwave current to cleaning gas passing through the unit 200. The dielectric filler 226 acts as a microwave antenna to broadcast the microwave current along the substantial length of the middle section 210. Additionally, the dielectric filler 226 prevents a plasma from forming in the area 230 of the unit 200. The inside surface 232 of the middle section 210 may have one or more slits 222 carved through the surface 232 to expose the dielectric filler 226. The slits 222 expose the cleaning gas passing through the unit 200 to the microwave current such that the cleaning gas is ignited into a plasma.

The unit 200 thus has the ability to function as both an RF choke during processing and as a remote plasma source during cleaning. By combining an RF choke and a remote plasma source into one unit 200, space is saved on the processing chamber and surrounding area. Additionally, by combining the RF choke and remote plasma source into a single unit 200, the remote plasma source is closer to the processing chamber and the plasma formed therein is less likely to ground or the radicals recombine before reaching the processing chamber. Higher currents and flow rates are thus possible.

In operation, during a process, such as a deposition process, RF power may be supplied to the chamber from an RF source 204. The RF source will travel along the end block 206 to the backing plate 202 and then to the processing chamber. The RF current will also travel back along the unit 200 seeking a path to ground. The RF current will travel along the outside surface of the end block 206, the outside of the middle section 210, and the outside surface of the end block 208 to ground. While traveling along the middle section 210, the RF current will encounter one or more ferrite disks 212 to dissipate the RF current. Additionally, the RF current may travel along one or more fins 214 that are coupled to the middle section 210 to increase the surface area of the ferrite disks 212 that the RF current is exposed to.

Once the deposition process is complete and the processing chamber needs cleaned, a cleaning gas may be introduced to the unit 200. A microwave current may be introduced to the inside of the unit 200 through the dielectric filler 226 and slits 222. The microwave current may rip apart the cleaning gas molecules to form a plasma that is fed to the processing chamber. Simultaneously, RF current may be supplied from the RF power source 204 to the processing chamber to maintain the plasma within the processing chamber during cleaning. Thus, RF current may flow along the outside of the unit 200 while microwave current is simultaneously provided to the inside of the unit 200.

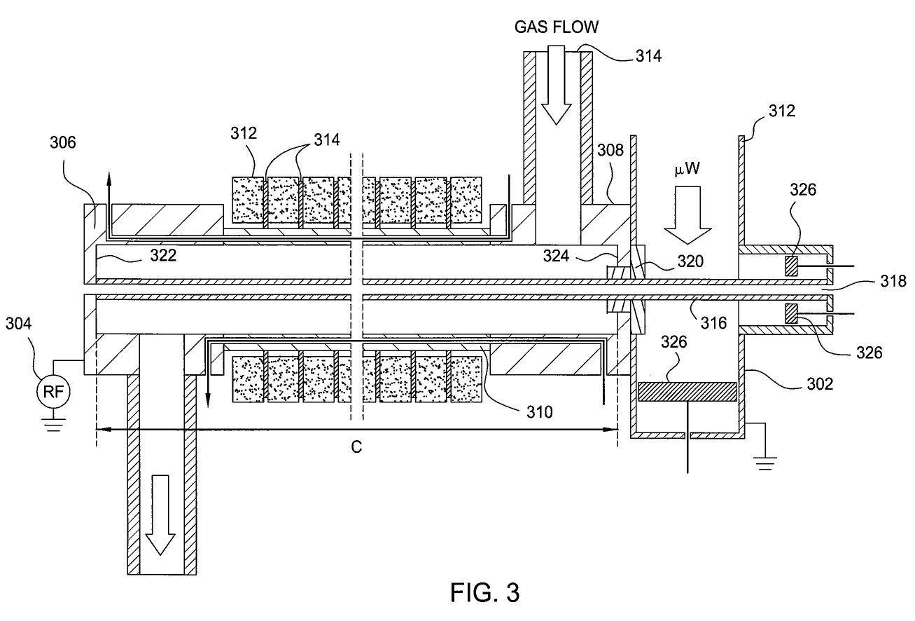

FIG. 3 is a schematic cross sectional view of a remote plasma source/RF choke unit 300 according to another embodiment of the invention. The unit 300 comprises an RF power source 304 coupled to an end block 306 of the unit 300. The unit 300 also comprises a second end block 308 coupled to a middle section 310 that connects the two end blocks 306, 308. The cleaning gas and processing gas may enter the unit 300 through a gas inlet 314. A microwave section 302 may be coupled to the end block 308. The microwave section 302 may also be coupled to ground. The microwave section 302 provides a waveguide to rod transition of the microwave current. A waveguide may be coupled to a microwave source entrance 312. The microwave enters the microwave section 302 where one or more tuners 326 tune the microwave and transition the microwave current onto a coaxial tube 316. The microwave current then travels along the coaxial tube 316 into the end block 308, middle section 310, and end block 306 to ignite a plasma within the unit 300. The coaxial tube 316 may extend from one end 324 of the unit 300 to a second end 322 of the unit 300. The coaxial tube 316 may comprise a material resistant to the ionized cleaning gas such as hard-anodized aluminum, aluminum oxide, aluminum nitride, and combinations thereof. The coaxial tube 316 may have a predetermined length as shown by arrows “C”. The coaxial tube 316 may be electrically insulated from the end block 308 by a dielectric insulator 320. To prevent overheating, the coaxial tube 316 a cooling passage 318 may be present within the coaxial tube 316. A cooling fluid may flow through the coaxial passage 318 to control the temperature of the coaxial tube 316. In one embodiment, the cooling fluid may flow counter to the gas flow. In another embodiment, the cooling fluid may flow in substantially the same direction as the gas flow. The plasma may form within the unit 300 around the coaxial tube 316.

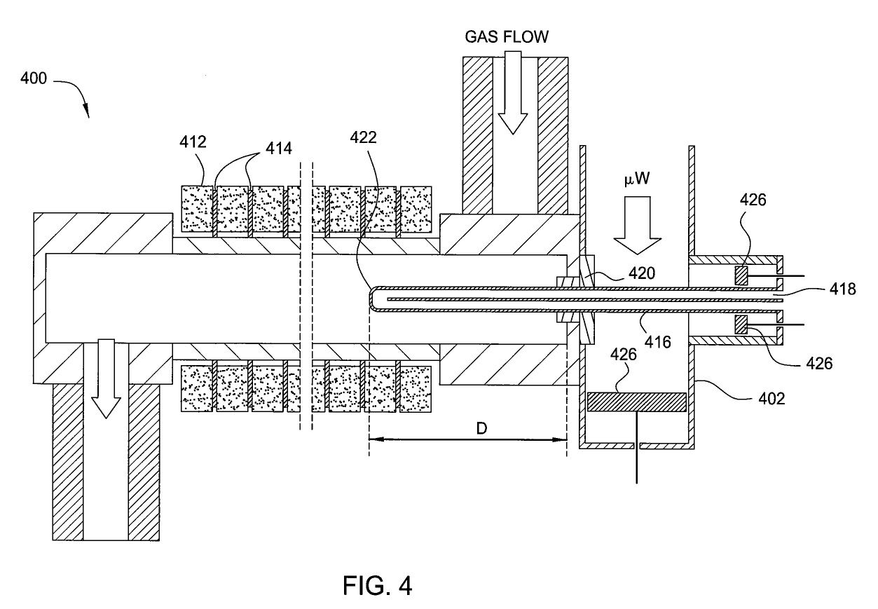

FIG. 4 is a schematic cross sectional view of a remote plasma source/RF choke unit 400 according to another embodiment of the invention. The coaxial tube 416 does not extend to the end of the unit 400 in FIG. 4. Rather, the end 422 of the coaxial tube 416 is a predetermined distance into the unit 400 and have a length shown by arrows “D”. The cooling passage 418 may flow back upon itself after reaching the end of the coaxial tube 416. A dielectric insulator 420 may insulate the coaxial tube 416 from the end block, and one or more tuners 426 in the microwave section 402 may tune the microwave current and aid in transitioning the microwave to the coaxial tube 416.

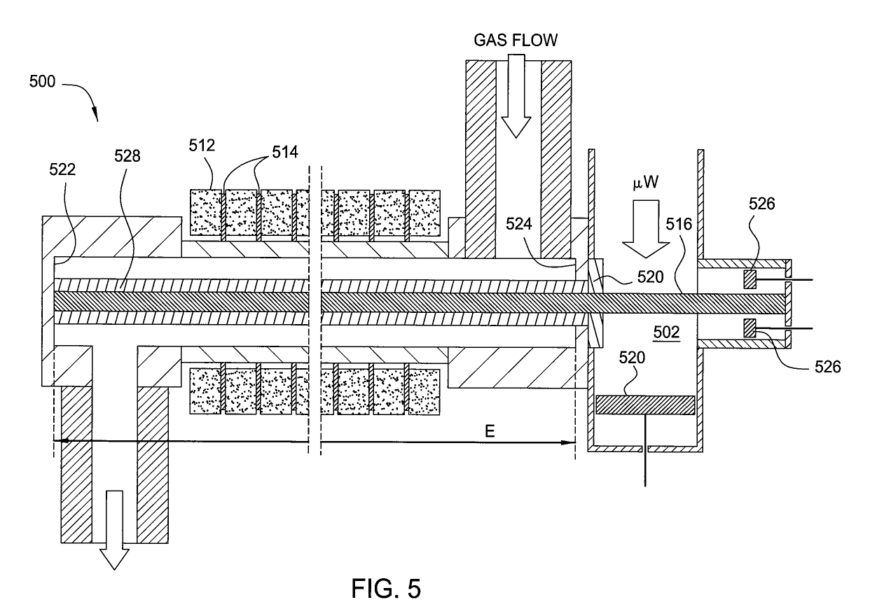

FIG. 5 is a schematic cross sectional view of a remote plasma source/RF choke unit 500 according to another embodiment of the invention. The embodiment shown in FIG. 5 is similar to the embodiment shown in FIG. 3, but the coaxial tube 516 is enclosed within an insulator 528 for the length of the coaxial tube 516 extending from one end 522 of the unit 500 to the other end 524 of the unit and have a length as shown by arrows “E”. A dielectric insulator 520 may isolate the coaxial tube 516 from the walls of the microwave section 502 when it passes into the end block. One or more tuners 526 may be present in the microwave section 502 to aid in transitioning a microwave current to the coaxial tube 516. While not shown, it is to be understood that a cooling channel may be present within the coaxial tube 516.

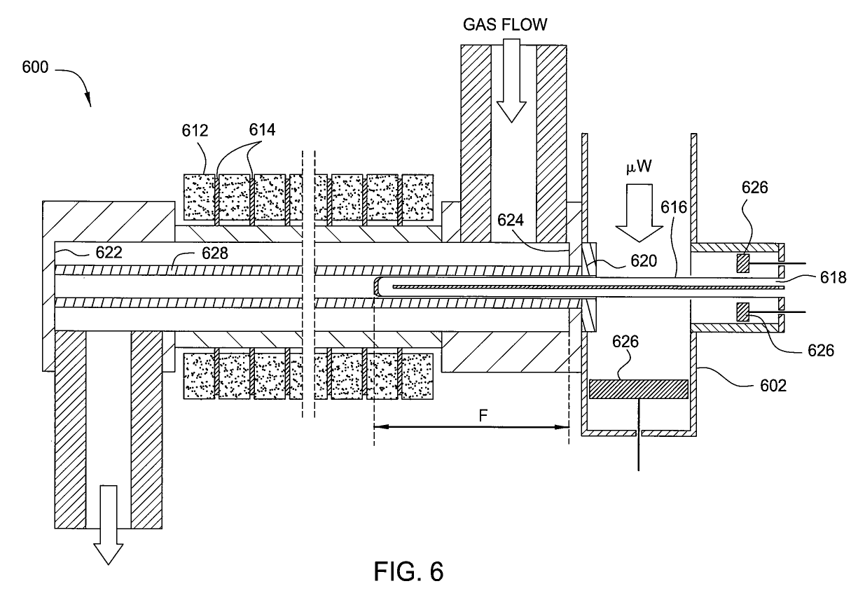

FIG. 6 is a schematic cross sectional view of a remote plasma source/RF choke unit 600 according to another embodiment of the invention. The coaxial tube 616 may extend a distance shown by arrows “F” between the ends 622, 624 of the unit 600, but the length may not cover the entire distance between the ends 622, 624. Rather, the insulator 628 that encompasses the coaxial tube 626 may extend from one end 622 to the other end 624. The coaxial tube 616 may still be insulated from the walls of the microwave section 602 by a dielectric insulator 620. A cooling channel 618 may be present within the coaxial tube 616 and turn back upon itself to exit the unit 600 on the same side from which it enters. Additionally, one or more tubers 626 may tune the microwave current and/or aid in transitioning the microwave current to the coaxial tube 616.

By combining an RF choke and a remote plasma source into a single unit, a smaller amount of space may be utilized. The RF choke may reduce parasitic plasma formation. The remote plasma source, by being within the RF choke, is closer to the processing chamber and thus, the plasma formed therein may reach the processing chamber with greater efficiency and have a smaller likelihood of dissipating.

While the foregoing is directed to embodiments of the present invention, other and further embodiments of the invention may be devised without departing from the basic scope thereof, and the scope thereof is determined by the claims that follow.

1. A remote plasma source, comprising:
a metal containing source body having a first end, a second end, and a center portion coupled between the first end and the second end, the source body having an inner surface extending between the first end and the second end through the central portion;
one or more dielectric antennas disposed within the center portion; and
one or more ferrite elements coupled to and at least partially surrounding an outer surface of the center portion.

2. The source of claim 1, wherein the inner surface has a plurality of offset, diametrically opposed, staggered slits carved therein such that a portion of the one or more dielectric antennas is exposed.

3. The source of claim 2, wherein the plurality of slits are evenly spaced along the inner surface.

4. The source of claim 2, wherein the one or more slits are perpendicular to a longitudinal axis of the inner surface of the source body.

5. The source of claim 1, wherein one or more cooling channels are bored through the central portion.

6. A remote plasma source, comprising:
a metal containing source body having a first end, a second end, and a center portion coupled between the first end and the second end, the source body having an inner surface extending between the first end and the second end through the central portion;
a conductive coaxial element extending within the source body and spaced from the inner surface; and
a dielectric spacer coupled between the first end and the conductive coaxial element.

7. The source of claim 6, wherein the first end comprises one or more movable tuning elements for coupling a microwave current to the conductive coaxial element.

8. The source of claim 6, wherein the conductive coaxial element comprises a cooling channel extending therethrough.

9. The source of claim 6, wherein the conductive coaxial element extends to the first end.

10. The source of claim 6, further comprising one or more ferrite elements coupled to and at least partially surrounding an outer surface of the central portion.

11. The source of claim 6, wherein one or more cooling channels are bored through the central portion.

12. An apparatus, comprising:
a processing chamber;
a remote plasma source, the remote plasma source having a metal containing source body comprising a first end, a second end, and a central portion coupled therebetween, the source body having an inner surface, the second end coupled to ground, and the first end coupled with the processing chamber;
an RF power source coupled to the first end of the remote plasma source;
a microwave power source coupled with the remote plasma source; and
a gas source coupled with the remote plasma source.

13. The apparatus of claim 12, wherein the remote plasma source further comprises:
one or more dielectric antennas disposed within the center portion; and
one or more ferrite elements coupled to and at least partially surrounding an outer surface of the center portion.

14. The apparatus of claim 13, wherein the inner surface has one or more slits carved therein such that a portion of the one or more dielectric antennas is exposed.

15. The apparatus of claim 14, wherein the one or more slits comprises a plurality of offset, diametrically opposed, staggered slits.

16. The apparatus of claim 12, wherein one or more cooling channels are bored through the central portion.

17. The apparatus of claim 12, further comprising:
a conductive coaxial element extending within the source body and spaced from the inner surface; and
a dielectric spacer coupled between the first end and the conductive coaxial element.

18. The apparatus of claim 17, wherein the first end comprises one or more movable tuning elements for coupling a microwave to the conductive coaxial element.

19. The apparatus of claim 17, wherein the conductive coaxial element comprises a cooling channel extending therethrough.

20. The apparatus of claim 17, wherein the conductive coaxial element extends to the first end.
